(19) United States
(12) Patent Application Publication
(10) Pub. No.: US 2022/0115574 A1
(43) Pub. Date: Apr. 14, 2022

(54) THERMOELECTRIC DEVICE AND FABRICATION

(71) Applicant: Worcester Polytechnic Institute, Worcester, MA (US)

(72) Inventors: Sathwik Bharadwaj Daralagodu Dattatreya Jois, West Lafayette, IN (US); Ashwin Ramasubramaniam, Sunderland, MA (US); Lakshminarayanapuram Ramdas Ram-Mohan, Westborough, MA (US)

(21) Appl. No.: 17/500,881

(22) Filed: Oct. 13, 2021

Related U.S. Application Data
(60) Provisional application No. 63/090,871, filed on Oct. 13, 2020.

(51) Int. Cl. H01L 35/04; H01L 35/34

(52) U.S. Cl. CPC H01L 35/04; H01L 35/16; H01L 35/34

(57) ABSTRACT

A method of fabricating a two dimensional thermoelectric device includes forming dissimilar atomic layers having quantum electron transport properties, and forming a well-defined interface between the dissimilar atomic layers for effecting a thermoelectric transport by exploiting a gradient in the material parameters between the layers. The resulting device defines an inclusion matrix of the dissimilar atomic layers such that the inclusion layer is confined within a matrix formed by the other atomic layer.

### RELATED APPLICATIONS

This patent application claims the benefit under 35 U.S.C. § 119(e) of U.S. Provisional Patent App. No. 63/090,871, filed Oct. 13, 2020, entitled “THERMOELECTRIC DEVICE AND FABRICATION,” incorporated herein by reference in entirety.

### BACKGROUND

Generating sustainable sources of energy to match the needs of the ever-increasing world population and to mitigate the impacts of climate change is one of the most important scientific challenges of the 21st century. Thermal-to-electrical energy conversion through thermoelectric devices have begun to play a crucial role in fulfilling future demands for clean energy. The market for thermoelectric generators is projected to grow from USD 460 million in 2019 to USD 741 million by 2025, at a compound annual growth rate (CAGR) of 8.3% during the forecast period. Increasing demand to recover the waste heat generated by various industries has become an important facet of energy balance and green energy usage. The thermoelectric device market can be classified into Low Temperature (<80° C.), Medium temperature (80°-500° C.) and High temperature (>500° C.) regimes. The low-temperature regime includes high-power mobile consumer electronics, and wearable electronics, among others.

### SUMMARY

A method of fabricating a two dimensional thermoelectric device includes forming dissimilar atomic layers having quantum electron transport properties, and forming a well-defined interface between the dissimilar atomic layers for effecting a thermoelectric transport by exploiting a gradient in the material parameters between the layers. The resulting device defines an inclusion matrix of the dissimilar atomic layers such that the inclusion layer is confined within a matrix formed by the other atomic layer.

Thermoelectric effects result from electrical properties of materials exposed to a thermal gradient, resulting in an electron flow. Configurations herein are based, in part, on the observation that thermoelectric effects can be difficult to scale to magnitudes needed for efficient power generation. Unfortunately, conventional approaches to thermoelectric heat dissipation and electrical harvesting suffer from the shortcoming that the bulk materials having such properties do not lend well to surface applications and often employ volatile and/or environmentally insensitive materials such as heavy metals in production.

Accordingly, configurations herein substantially overcome the above-described shortcomings of bulk thermoelectric materials by providing a quantum transport design and manufacturing system for producing an ultra-efficient in-plane electronic and thermoelectric device to fulfill future demands for devices based on quantum electronics and clean energy solutions.

Traditionally, semiconductor superlattices and heterostructures have been used to construct thermoelectric devices. However, in such structures, it is experimentally difficult to achieve the efficiency predicted by the theory, since a large number of parameters have to be optimized. In this regard, two-dimensional (2D) materials such as graphene and transition-metal dichalcogenides (TMDC) have attracted tremendous attention due to their unique physical and chemical properties. Generation of a two dimensional matrix or material based on TMDCs can leverage a gradient in the material parameters to enhance the thermoelectric efficiency.

A two dimensional thermoelectric device as defined herein includes a transition-metal dichalcogenide (TMDC) heterostructure having an inclusion confined within a matrix, defining the heterostructure, such that the inclusion is based on a material suited for thermoelectric transport. The resulting monolayer structure defines the transition-metal dichalcogenide heterostructure.

The matrix of the opposed atomic layers may be formed on a silicon wafer by semiconductor fabrication techniques, among others. The TMDC heterostructure as defined herein is usually based on a matrix forming a triangular arrangement. The constituent layers define a triangular orientation of atoms forming a heterointerface between the monolayers. The heterostructure typically has a thickness not greater than 5 angstroms, only 10% of a conventional 50 angstroms for bulk materials, and is based on a layer of three atoms in a matrix arrangement. The side and top views of the matrix and triangular orientation are depicted below in FIGS. 2A-2B.

Practical applications of the two dimensional heterostructure with thermoelectric properties include disposing or deploying the heterostructure in conjunction with a heat sink of an electrical appliance. The thermoelectric heterostructure has an electrical connection to an electrical source coupled to the electrical appliance for directing electrons, based on the thermoelectric properties, to the electrical appliance. For example, a computing device such as a cellphone/table/personal device/laptop applies the thermoelectric material to a processor, which generates heat during normal operation. The thermoelectric flow produced is connected back into the battery/charging circuit of the device to supplement the battery power.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a context diagram of a thermoelectric structure invoked by the disclosed approach;

FIGS. 2A and 2B show a schematic view of a triangular inclusion in the thermoelectric structure of FIG. 1;

FIGS. 3A-3D show energy density of the disclosed thermoelectric structure;

FIGS. 4A-4B show an atomic structure of the disclosed thermoelectric structure;

FIGS. 5A-5B show semiconductor energy levels in the thermoelectric structure of FIGS. 1-4B;

FIG. 6 shows conduction and valence bands in the semiconductor of FIGS. 5A-5B; and

FIGS. 7A-7B show electron scattering rates of semiconductors formed as in FIGS. 2A-4B.

### DETAILED DESCRIPTION

Increasing demands for renewable sources of energy has been a major driving force for developing efficient thermoelectric materials. Two-dimensional (2D) transition-metal dichalcogenides (TMDC) have emerged as promising candidates for thermoelectricity due to their large effective masses and low thermal conductivity. In this article, we study the thermoelectric performance of lateral TMDC heterostructures within a multiscale quantum transport framework. Both n-type and p-type lateral heterostructures are considered for all possible combinations of semiconducting TMDCs: MoS2, MoSe2, WS2, and WSe2. The band alignment between the materials is found to play a crucial in enhancing the thermoelectric figure-of-merit (ZT) and power factor far beyond the pristine TMDCs.

In particular, a room-temperature ZT value of n-type WS2 with WSe2 triangular inclusions is five times larger than the pristine WS2 monolayer. p-type MoSe2 with WSe2 inclusions is also shown to have a room-temperature ZT value about two times larger than the pristine MoSe2 monolayer. The peak power factor values calculated here, are the highest amongst the gapped 2D monolayers at room temperature. Hence, 2D lateral TMDC hetero structures opens new avenues to construct ultra-efficient in-plane thermoelectric devices.

Thermoelectric devices can play a pivotal role in fulfilling future demands for clean energy. A good thermoelectric material must have a high thermoelectric figure-of-merit ZT, defined as

$$ZT = \frac{σ {S}^{2} T}{{κ}_{e} + {κ}_{ph}}$$

where T is the absolute temperature, σ is the electrical conductance, S is the Seebeck coefficient, κe is the electronic thermal conductivity, and κph is the lattice phonon thermal conductivity. In bulk materials, the value of ZT is limited by σ and S varying in inverse proportion, and κe and σ varying in direct proportion.

Hence, thermoelectricity was historically believed to be an inefficient source of energy for practical application. However, through the use of nanostructures, one could achieve a substantial increase in the value of ZT by reducing the dimensionality of the system. The density of electron states per unit volume increases in lower dimensions, thereby resulting in an enhancement in ZT. Since then, the field of thermoelectricity has focused on: a) increasing S and σ independently through quantum confinement effects, and b) decreasing Kph by systematically controlling phonon contributions. Additionally, other techniques such as band-gap engineering, carrier-pocket engineering, energy filtering, and semimetal-semiconductor transition have been developed to engineer the thermoelectric properties of nanostructures.

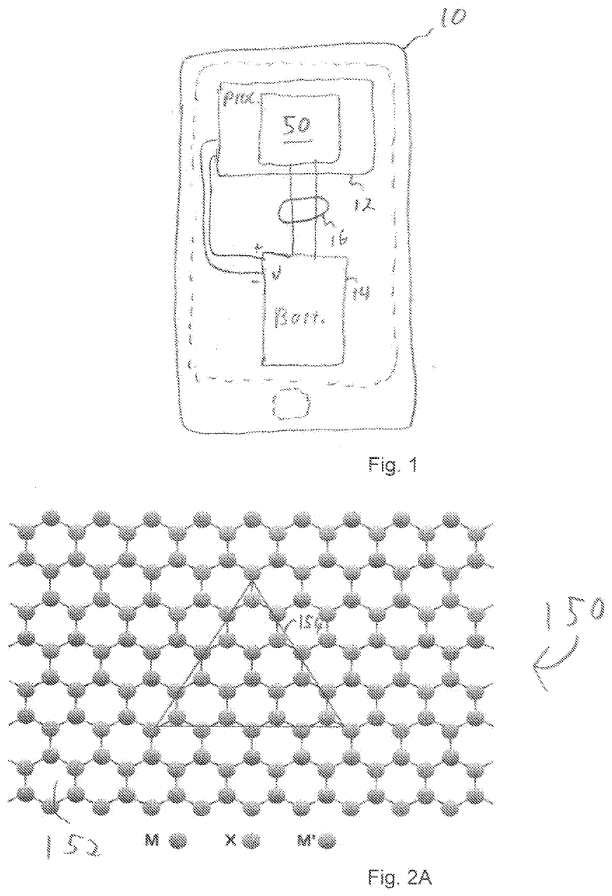

FIG. 1 is a context diagram of a thermoelectric structure invoked by the disclosed approach. Referring to FIG. 1, personal electronic devices 10 are commonplace, often taking the form of cellphones, smartphones and tablets. These devices employ a processor 12 and related electronics and memory, and typical generate substantial heat from electrical resistance. A rechargeable battery 14 defines a power source, and is periodically recharged. A thin, surface mountable thermoelectric device 50 as disclosed herein is mounted on or in thermal communication with the processor 12. Heat from the processor induces the thermoelectric device 50 to generate a current (or voltage source), and a connection 16 to the battery provides recharge power to mitigate battery drain. The disclosed approach therefore improves battery longevity combined with absorbing heat from the processor.

In the disclosed approach, the thermoelectric device 50 may take the form of two dimensional heterostructure device comprising having thermoelectric properties disposed on a heat sink of an electrical appliance such as the personal device 10. In the example arrangement, the device 50 includes opposed atomic layers defining an inclusion layer for defining a thermoelectric response, and an electrical connection 16 to an electrical appliance for directing electrons based on the thermoelectric properties to the electrical appliance. A heat sink defined on the processor 12 is disposed for thermal transfer from the electrical appliance for generating a thermoelectric current. This may be simply an aluminum panel, conductive paste, or simply direct placement on the processor surface 12.

FIGS. 2A and 2B show a schematic view of a triangular inclusion in the thermoelectric structure of FIG. 1. Referring to FIGS. 1 and 2A-2B, the thermoelectric device 50 result from forming atomic layers 150 as a monolayer heterostructure on a silicon wafer substrate 12′ or similar substrate. In the examples herein, a layered structure of the atomic layers 152 and an inclusion layer defines a transition-metal dichalcogenide heterostructure. The layers 152 form triangular inclusions 154 between the atomic layers for defining an inclusion matrix, discussed further below.

FIG. 2A depicts a schematic representation of a triangular inclusion 154 in 2D materials is displayed. Here, M′X2 material is confined within the MX2 matrix. In FIG. 2B, an in-plane thermoelectric device using lateral TMDC heterostructures is shown. A 2D monolayer is placed on an oxide substrate 12′ that can be grown on p+ silicon material.

Traditionally, semiconductor superlattices and heterostructures have been used to construct efficient thermoelectric devices. However, in such structures, it is experimentally difficult to achieve the predicted efficiency, since a large number of parameters have to be optimized. In this regard, two-dimensional (2D) materials such as graphene and transition-metal dichalcogenides (TMDC) have attracted tremendous attention due to their unique physical and chemical properties. The high degree of flexibility of 2D materials to tune the electrical and thermal properties, makes them ideal candidates for thermoelectric applications. A prototypical 2D material, graphene, exhibits a power factor (PF) value as high as 34.5 mWm-1K-2 at room temperature. However, it has limited thermoelectric applications due to the extremely high thermal conductivity (2000-4000 Wm-1K-1 for freely suspended samples at room temperature). In comparison, monolayer (1L) TMDCs maintain a very low thermal conductance due to significantly lower phonon mean free paths. Hence, TMDCs have tremendous potential to realize in-plane thermoelectric and Peltier cooling devices.

There have been several first-principles studies in the literature, calculating the thermoelectric quantities in 1L and layered TMDCs. P-type MoS2 1L and n-type WSe2 1L were observed to have maximum ZT values at room temperature and at higher temperatures, respectively. Also, bilayer MoS2 is observed to have a PF of 8.5 mWm-1K-2, which is highest amongst materials with a non-zero bandgap. Yet the conductance and ZT values observed in TMDCs are much lower than the corresponding quantities in traditional thermoelectric materials such as Bi2Te3, and phonon-glass electron crystals. There are opportunities to boost the thermoelectric performance in TMDCs through the formation of heterostructures.

Similar crystal structure and comparable lattice constants observed in MX2 (M=Mo, W; X=S, Se) monolayers have motivated the construction of lateral TMDC heterostructures. Experimentally, such structures are fabricated through multistep chemical vapor deposition techniques, one-pot synthesis, and omnidirectional epitaxy. In traditional thermoelectric materials, such as Bi2Te3, quantum confinement through the formation of heterostructures have been demonstrated to enhance the figure-of-merit. Such an enhancement can be anticipated in lateral 2D TMDC heterostructures as well.

Configurations herein present thermoelectric performance of lateral TMDC heterostructures within a multiscale quantum transport framework with inputs from first-principles calculations. Particular configurations employ triangular inclusions, as shown in FIGS. 2A and 2B, since 2D TMDCs are typically grown as triangular flakes. Configurations include both n-type and p-type lateral heterostructures, for all possible combinations of semiconducting TMDC monolayers: MoS2, MoSe2, WS2, and WSe2. n-type WS2 with WSe2 triangular inclusions is found to have ZT≈1 at room temperature, which is five times larger than ZT value of pristine n-type WS2 1L. The peak power factor for the lateral TMDC heterostructures obtained here, are the highest amongst the gapped 2D 1L reported at room temperature.

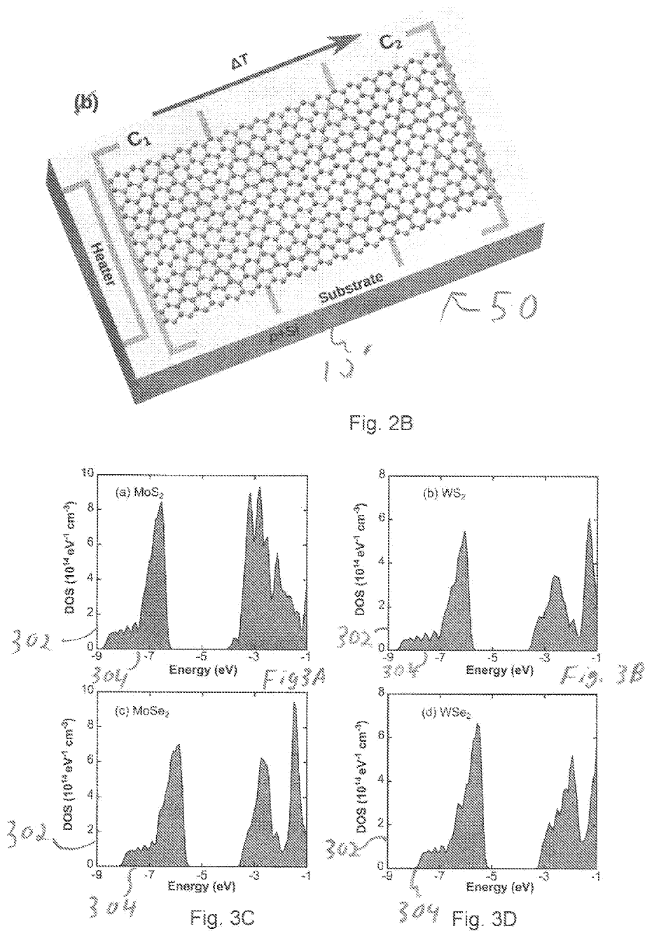

FIGS. 3A-3D show energy density of the disclosed thermoelectric structure. Referring to FIGS. 2A-3D, in the thermoelectric device 50, thermoelectric properties are evaluated using the Boltzmann transport theory under the relaxation time approximations. Within this framework, the kinetic definitions of the conductance, Seebeck coefficient, and the electrical thermal conductivity are given by:

$$σ = {e}^{2} {ℐ}_{0} , \\ S = \frac{1}{eT} \frac{{ℐ}_{1}}{{ℐ}_{0}} , \\ {κ}_{e} = \frac{1}{T} [ {ℐ}_{2} - \frac{{ℐ}_{1}^{2}}{{ℐ}_{0}} ]$$

$$with$$

$${ℐ}_{n} = \int {dEv}^{2} τ ( E ) g ( E ) {( E - {μ}_{F} )}^{n} ( - \frac{\partial {f}_{0}}{\partial E} )$$

where e is the elementary charge, g(E) is the density of states, ν=|∇ₖEₙ(k)|/n is the carrier velocity, f₀(E)=1/(1+e^{(E-μ}F)/kB T) is the Fermi-Dirac distribution function, μ_{F} is the Fermi level, and τ(E) is the total scattering time. The density of states g(E) is extracted from the electronic band structure obtained using the density functional theory (DFT) calculations within the local-density approximations (LDA). FIGS. 3A-3D show the density of states as a function of energy for MoS₂, WS₂, MoSe₂ and WSe₂ 1L. g(E) is normalized with the unit-cell area and the corresponding layer thickness. The PF and ZT value are sensitive to the small variations of g(E) near the band edges.

To determine τ(E), we need to consider both the intrinsic and extrinsic scattering rates. According to Matthiessen's law:

$${τ ( E )}^{- 1} = {{τ}_{e} ( E )}^{- 1} + {{τ}_{ph} ( E )}^{- 1}$$

where τₑ is the extrinsic carrier scattering time arising from the material inclusions, and τₚₕ is the total intrinsic scattering time arising from all the acoustic and optical phonon mode contributions. The intrinsic scattering rate τₚₕ is assumed to remain unaltered from the pristine 1L, a commonly used assumption while studying nanostructured thermoelectric materials.

In FIGS. 3A-3B, the density of states per unit energy per unit area obtained from DFT calculations on axis 302 is plotted as a function of energy on axis 304 for 1L of MoS2 (FIG. 3A), WS2 (FIG. 3B); MoSe2 (FIG. 3C), and WSe2 in FIG. 3D. DFT calculations were performed within local-density approximations (LDA), and the spin-orbit effects are neglected. Hence, all bands are doubly degenerate.

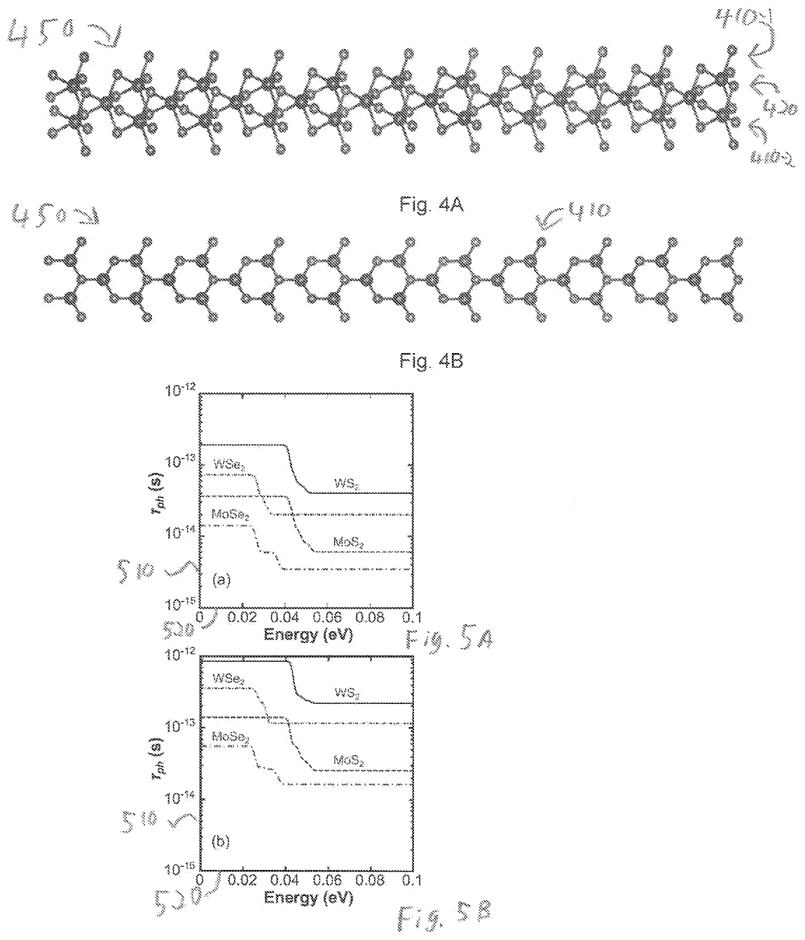

FIGS. 4A-4B show an atomic structure of the disclosed thermoelectric structure. The disclosed approach includes a method of fabricating a two dimensional in-plane thermoelectric device, 450, including forming a plurality of atomic layers 410-1 . . . 410-2 (410 generally), such that each atomic layer 410 has quantum electron transport properties. Fabrication includes forming an inclusion layer 420 between the opposed atomic layers 410 for effecting thermoelectric transport by exploiting a gradient in material parameters of the atomic layers for increasing a thermoelectric efficiency of a resulting thermoelectric current. Electrodes may be attached at appropriate corresponding locations to induce a voltage and current from the thermoelectric response. The inclusion layer 420 results as an inclusion matrix confined within the respective atomic layers, based on the triangular 154 insertion.

FIG. 4A shows a side view of the layered structure, and FIG. 4B shows a top view, similar to FIG. 2A. In the example of FIGS. 4A and 4B, opposed atomic layers 410 reside in a parallel orientation for forming the inclusion matrix of layer 420, such that the inclusion matrix is confined between the atomic layers based on a triangular inclusion. The opposed atomic layers are typically formed on a substrate 12′ adapted for heat transfer.

In the example approach defined herein, the fabricated layers 410, 420 therefore form a two-dimensional thermoelectric material, including a transition-metal dichalcogenide (TMDC) heterostructure having an inclusion confined within a matrix defined by the heterostructure. The inclusion is based on a material for forming a thermoelectric transport. The layers define a triangular 154 orientation of atoms forming a heterointerface between the layers.

FIGS. 5A-5B show semiconductor energy levels in the thermoelectric structure of FIGS. 1-4B; In FIGS. 5A-5B, the total phonon scattering time 510 versus energy 520 at room temperature for pristine n-type and p-type 1L TMDCs. The total phonon scattering time versus energy for K-valley electrons (FIG. 5A), and (FIG. 5B) K-valley holes are plotted for TMDCs at temperature T=300 K. Acoustic and optical phonon modes correspond to the transition K→{K, K′, Q, Q′}, via corresponding zeroth and first-order deformation potentials. The optical phonon modes emerge as steps in the scattering rate. In the family of TMDC 1L, MoSe2 (WS2) has the strongest (weakest) interaction with phonons. In general, WX₂ has a greater phonon-limited electrical conductivity than MoX₂.

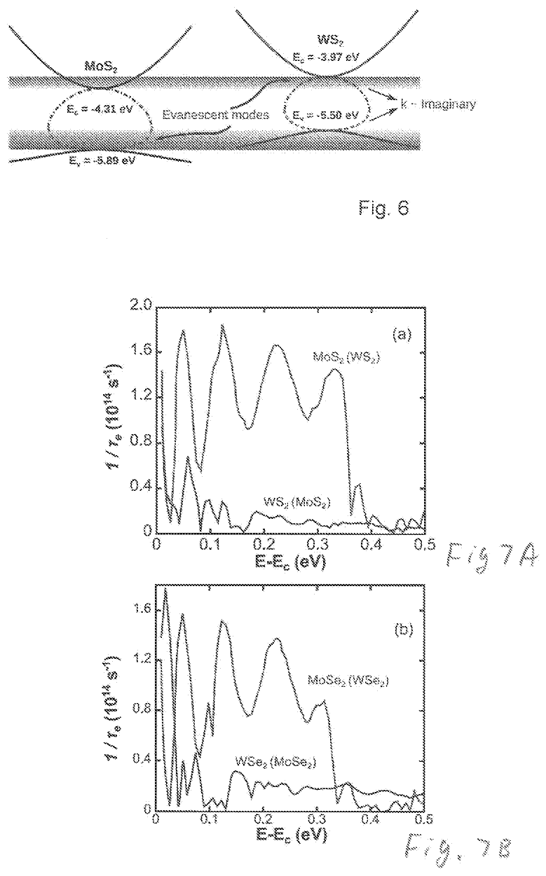

To calculate the carrier scattering time τₑ, the example configuration employs a multiscale quantum transport framework informed by first-principles calculations. Material inclusions break the translation symmetry of the system. Hence, the scattering in these structures can occur via both propagating (real wavevector) and evanescent modes (purely imaginary wavevector). The example of FIG. 6 plots the heterointerface formed between MoS₂ and WS₂ 1L. In FIG. 6, the conduction and valance band near the K-point are plotted for MoS2 and WS2 1L. In the presence of scattering centers, below the energy −3.97 eV (for n-type MoS2), and above the energy −5.89 eV (for p-type WS2) carrier transport across the interface, occurs only through the evanescent bands. Electronic structure calculations dictate that MoS₂ 1L (E_{c}=−4.31 eV) has a lower conduction band (CB) minimum than WS₂ (E_{c}=−3.97 eV) 1L. When an electron in the CB with energy −4.31 eV≤E<−3.97 eV is injected from the MoS₂ to WS₂ 1L, scattering occurs only through the evanescent modes. Similarly, for carriers in the valence band of p-type WS2, with energy −5.50 eV≥E>−5.89 eV (corresponding to the valence band maximum of MoS2) only evanescent modes are available for scattering. Evanescent modes are situated within the bandgap, and result in exponentially decaying contributions to the scattered wavefunction.

The main results for the peak power factor and ZT values for the n-type and p-type TMDC lateral heterostructures are listed in Table I and Table II, respectively. In these tables, the notation A(B) represents that the material B inclusions are confined within the matrix of the material A. The material inclusion is considered here to be a substantially equilateral triangle.

TABLE I

| 1L heterostructure | PF (10⁻³ WK⁻²m⁻¹) | | | ZT | | | Pristine 1L (at 300 K) | | |
|---|---|---|---|---|---|---|---|---|---|
| A (B) | 300 K | 500 K | 800 K | 300 K | 500 K | 800 K | A | ZP_{1L} [21] | ZP_{1L} [22] |
| MoS₂ (WS₂) | 0.365 | 0.293 | 0.181 | 0.093 | 0.124 | 0.125 | MoS₂ | 0.22 | 0.25 |
| MoS₂ (MoSe₂) | 0.335 | 0.256 | 0.167 | 0.084 | 0.109 | 0.115 | MoS₂ | 0.22 | 0.25 |
| WS₂ (MoS₂) | 4.565 | 3.896 | 2.371 | 0.598 | 1.231 | 1.641 | WS₂ | 0.22 | 0.23 |
| WS₂ (WSe₂) | 5.977 | 4.476 | 2.470 | 0.997 | 1.611 | 1.806 | WS₂ | 0.22 | 0.23 |
| MoSe₂ (WSe₂) | 0.500 | 0.367 | 0.200 | 0.173 | 0.227 | 0.205 | MoSe₂ | 0.35 | 0.36 |
| MoSe₂ (MoS₂) | 0.485 | 0.362 | 0.199 | 0.165 | 0.223 | 0.205 | MoSe₂ | 0.35 | 0.36 |
| WSe₂ (MoSe₂) | 1.929 | 1.457 | 0.815 | 0.485 | 0.816 | 0.875 | WSe₂ | 0.33 | 0.38 |
| WSe₂ (WS₂) | 1.954 | 1.468 | 0.819 | 0.488 | 0.821 | 0.879 | WSe₂ | 0.33 | 0.38 |

In Table I, the peak power factor (PF) and the figure-of-merit ZT are listed for n-type monolayer (1L) TMDC heterostructures at temperatures 300 K, 500 K, and 800 K. Here, the notation A(B) represents that the material B inclusions are confined within the matrix of the material A. The material inclusion is equilateral triangle of the side length 8 nm. The density of inclusions is consider to be, n_{d}=10¹² cm. For comparison, we have listed the room temperature ZT values for pristine 1L TMDCs.

It can be observed that the n-type WS₂(WSe₂), and p-type MoSe₂(WSe₂) have the maximum ZT values at room temperature. On the other hand, n-type WS₂(WSe₂), n-type WS₂(MoS₂), and p-type MoS₂(MoSe₂) have larger ZT values at higher temperatures. In Tables I and II, for comparison, we have listed the room temperature ZT values for pristine 1L TMDCs. For the n-type WS₂ 1L we observe up to five times larger ZT value with WSe₂ inclusions as compared to a pristine n-type WS₂ 1L. Similarly, for p-type MoSe₂ with WSe₂ inclusion, we observe an enhancement by a factor of two in the ZT values while compared to a pristine MoSe₂ 1L. In general, ZT values increase with temperature, as there is a multiplicative factor of temperature.

The calculated peak value of the PF for n-type WS₂(WSe₂) and WS₂(MS₂) 1L at room temperature is 5.977 mWK⁻² m⁻¹ and 4.565 mWK⁻² m⁻¹, respectively. These values are about twice the peak PF value ob-served in pristine TMDC 1L. Moreover, they are of the same order of magnitude as the observed PF in the traditional thermoelectric materials, such as Bi₂Ti₃ (5.2 mWK⁻² m⁻¹) and BiSbTe (5.4 mWK⁻² m⁻¹) crystals.

In Table I, it can be observed that n-type MoS₂(WS₂) and MoS₂(MoSe₂) have significantly lower thermoelectric values compared to a pristine MoS₂ 1L. Similarly, p-type WSe₂(WS₂) and WSe₂(MoSe₂) have significantly lower thermoelectric values compared to a pristine WSe₂ 1L (see Table II). These phenomena can be explained as a direct consequence of band alignment.

TABLE II

| 1L heterostructure | PF (10⁻³ WK⁻²m⁻¹) | | | ZT | | | Pristine 1L (at 300 K) | | |
|---|---|---|---|---|---|---|---|---|---|
| A (B) | 300 K | 500 K | 800 K | 300 K | 500 K | 800 K | A | ZP_{1L} [21] | ZP_{1L} [22] |
| MoS₂ (WS₂) | 1.940 | 1.862 | 1.315 | 0.407 | 0.713 | 0.871 | MoS₂ | 0.47 | 0.53 |
| MoS₂ (MoSe₂) | 4.076 | 3.213 | 2.001 | 0.648 | 1.115 | 1.289 | MoS₂ | 0.47 | 0.53 |
| WS₂ (MoS₂) | 0.895 | 0.779 | 0.568 | 0.274 | 0.407 | 0.486 | WS₂ | 0.43 | 0.42 |
| WS₂ (WSe₂) | 1.274 | 1.203 | 0.873 | 0.370 | 0.607 | 0.736 | WS₂ | 0.43 | 0.42 |
| MoSe₂ (WSe₂) | 2.272 | 1.826 | 1.060 | 0.714 | 1.004 | 1.045 | MoSe₂ | 0.38 | 0.39 |
| MoSe₂ (MoS₂) | 2.015 | 1.554 | 0.945 | 0.560 | 0.861 | 0.934 | MoSe₂ | 0.38 | 0.39 |
| WSe₂ (MoSe₂) | 0.034 | 0.023 | 0.014 | 0.015 | 0.017 | 0.016 | WSe₂ | 0.34 | 0.35 |
| WSe₂ (WS₂) | 0.023 | 0.017 | 0.011 | 0.011 | 0.013 | 0.013 | WSe₂ | 0.34 | 0.35 |

FIGS. 7A and 7B show electron scattering rates of semiconductors formed as in FIGS. 2A-4B. In FIGS. 7A-7B, the electron scattering rates versus energy for a K-valley electron are plotted for transport in FIG. 7A, MoS2 (WS2) & WS2 (MoS2), and FIG. 7B, MoSe2 (WSe2) & WSe2(MoSe2) 1L heterostructures.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method of fabricating a two dimensional in-plane thermoelectric device, comprising:
forming a plurality of atomic layers, each atomic layer of the plurality of atomic layers having quantum electron transport properties; and
forming an inclusion layer between the opposed atomic layers for effecting thermoelectric transport by exploiting a gradient in material parameters of the atomic layers for increasing a thermoelectric efficiency of a resulting thermoelectric current.

2. The method of claim 1 further comprising forming the inclusion layer as an inclusion matrix confined within the respective atomic layers.

3. The method of claim 1 further comprising forming the atomic layers as a monolayer heterostructure on a silicon wafer.

4. The method of claim 1 wherein a layered structure of the atomic layers and inclusion layer defines a transition-metal dichalcogenide heterostructure.

5. The method of claim 1 further comprising forming a triangular inclusion between the atomic layers for defining the inclusion matrix.

6. The method of claim 1 further comprising forming opposed atomic layers in a parallel orientation for forming the inclusion matrix, the inclusion matrix confined between the atomic layers and based on a triangular inclusion, the opposed atomic layers formed on a substrate adapted for heat transfer.

7. A two dimensional thermoelectric material, comprising:
a transition-metal dichalcogenide (TMDC) heterostructure having an inclusion confined within a matrix defined by the heterostructure, the inclusion based on a material for forming a thermoelectric transport.

8. The material of claim 7 wherein the matrix forms a triangular arrangement.

9. The material of claim 7 wherein the layers define a triangular orientation of atoms forming a heterointerface between the layers.

10. A two dimensional heterostructure device having thermoelectric properties disposed on a heat sink of an electrical appliance, further comprising:
opposed atomic layers defining an inclusion layer for defining a thermoelectric response;
an electrical connection to an electrical appliance for directing electrons based on the thermoelectric properties to the electrical appliance; and
a heat sink disposed for thermal transfer from the electrical appliance for generating a thermoelectric current.

11. The device of claim 10 wherein the opposed atomic layers and the resulting inclusion layer are formed from a two-dimensional transition-metal dichalcogenide heterostructure.

12. The apparatus of claim 10 wherein the device has a thickness not greater than 5 angstroms and is based on a layer of three atoms in a matrix arrangement.
